(19) United States
(12) Patent Application Publication
(10) Pub. No.: US 2023/0318247 A1
(43) Pub. Date: Oct. 5, 2023

(54) PACKAGE WITH MULTIPLE PHOTONIC INTEGRATED CIRCUIT DIES OPTICALLY COUPLED WITH EACH OTHER

(71) Applicant: INTEL cORPORATION, Santa Clara, CA (US)

(72) Inventors: Eleanor Patricia Paras RABADAM, Folsom, CA (US); Guiyun BAI, Chandler, AZ (US); Sanjeev GUPTA, Santa Rosa, CA (US); Ronald SPREITZER, Phoenix, AZ (US); Jonathan DOYLEND, Morgan Hill, CA (US); Ankur AGRAWAL, Chandler, AZ (US); Boping XIE, San Ramon, CA (US); Sushrutha Reddy GUJJULA, Chandler, AZ (US); Jason GARCIA, Scottsdale, AZ (US); Kenneth BROWN, Tempe, AZ (US); Dan WANG, San Jose, CA (US); Daniel GRODENSKY, Caesarea (IL); Israel PETRONIUS, Haifa (IL); Konstantin MATYUCH, Netanya (IL)

(21) Appl. No.: 17/710,881

(22) Filed: Mar. 31, 2022

(51) Int. Cl. H01S 3/04

(52) U.S. Cl. CPC H01S 3/0405

(57) ABSTRACT

Embodiments herein relate to systems, apparatuses, or processes directed to a package that includes multiple PICs in the package that are optically coupled with each other. In embodiments, the package may include discrete electronic and optical components, and thermal management solutions for co-packaging of multiple PICs. Other embodiments may be described and/or claimed.

### FIELD

Embodiments of the present disclosure generally relate to the field of package assemblies, and in particular package assemblies that include photonic integrated circuit (PIC) dies.

### BACKGROUND

Continued reduction in end product size of LiDAR (Light Detection and Ranging) optical sensors for Autonomous Vehicles is a driving force for the development of reduced size system in package components.

### BRIEF DESCRIPTION OF THE DRAWINGS

FIGS. 1A-1D illustrate a top-down view and cross section side views of a package that includes multiple PICs that are optically coupled with each other and that include a thermal electric cooler (TEC), in accordance with various embodiments.

FIGS. 2A-2F illustrate stages in a manufacturing process for creating a package that includes multiple PICs that are optically coupled with each other, in accordance with various embodiments.

FIGS. 3A-3C illustrate a top-down and cross section side views of a package that includes multiple PICs that are optically coupled with each other with heat spreaders coupled with the multiple PICs, in accordance with various embodiments.

FIGS. 4A-4E illustrate stages in a manufacturing process for creating a package that includes multiple PICs that are optically coupled with each other with heat spreaders coupled with the multiple PICs, in accordance with various embodiments.

FIG. 5 illustrates a top-down view and a cross section side view of a package that includes multiple PICs that are optically coupled with each other, and that are surrounded by a heat spreader with a cut out, in accordance with various embodiments.

FIG. 6 illustrates a top-down view and a cross section side view of a package that includes multiple PICs that are optically coupled with each other with a first substrate physically coupled with a first side of the multiple PICs and a second substrate physically coupled with a second side of the multiple PICs opposite the first side, in accordance with various embodiments.

FIGS. 7A-7E illustrate stages in a manufacturing process for creating a package that includes multiple PICs that are optically coupled with each other with a first substrate physically coupled with a first side of the multiple PICs and a second substrate physically coupled with a second side of the multiple PICs opposite the first side, in accordance with various embodiments.

FIG. 8 illustrates a cross section side view of a package that includes multiple PICs that are optically coupled with each other, where the multiple PICs are physically coupled with an optical bench that includes Invar, and are thermally managed by a TEC, in accordance with various embodiments.

FIG. 9 illustrates a cross section side view of a package that includes multiple PICs that are optically coupled with each other, where the multiple PICs are thermally managed by multiple TEC, in accordance with various embodiments.

FIG. 10 illustrates a cross section side view of a package that includes multiple PICs that are optically coupled with each other and surrounded by a chassis that includes a cut out to thermally couple a TEC with the multiple PICs, in accordance with various embodiments.

FIG. 11 illustrates a top-down view of a layout of a package that includes multiple PICs that are optically coupled with each other, with the package including fiber-optic components, in accordance with various embodiments.

FIG. 12 illustrates an example of a process for manufacturing a package that includes multiple PICs that are optically coupled with each other, in accordance with various embodiments.

FIG. 13 schematically illustrates a computing device, in accordance with embodiments.

### DETAILED DESCRIPTION

Embodiments of the present disclosure may generally relate to systems, apparatus, and/or processes directed to a package that include multiple PICs in the package that are optically coupled with each other. In embodiments, the package may include discrete electronic and optical components. The package may be surrounded by housing that may be used in part for thermal management. In embodiments, the housing may include openings to access optical components, for example optical components used to optically couple the multiple PICs within the package. In embodiments, a PIC may include, but is not limited to, a transceiver, a LiDAR transceiver, a laser, a tunable external feedback laser (TEFL), or a wavelength switchable laser array (WSLA).

In embodiments, the multiple PICs may be physically coupled with a substrate that may include an optical bench to provide alignment stability with the multiple PICs, particularly with respect to their optical coupling. One or more thermal management features, which may use to dissipate, route, or, otherwise adjust for heat generated by PICs within a package, may include but are not limited to TECs, thermal interface materials (TIMs), heat spreaders, and the like. These thermal management features may be integrated into the package and/or may be thermally coupled with the package.

In embodiments, the thermal management features may be used to support different thermal setpoints and different thermal tolerances for each of the different PICs within the package to meet electrical performance requirements at the required temperatures. In addition, various materials may be chosen to minimize differences between a coefficient of thermal expansion (CTE) of various components within the package to further decrease expansion differences during heat of operation of the package in order to minimize optical alignment issues within the package.

In addition, in embodiments, the PICs may be coupled with interposers that may be used to electrically couple the PIC with a substrate, which may reduce or eliminate the need for wire bonding or wire bond pads within the package. In embodiments, the PICs may be attached to substrates or other components within the package using a flip chip assembly process. In embodiments, these packages may be used for silicon photonics-based LiDAR systems, for example, to increase sensor capability and functionality within autonomous vehicles. These embodiments facilitate the addition of more sensors within a constrained vehicle space by facilitating the reduction of the form factor of these LiDAR systems.

Legacy systems include using an external laser component outside of a PIC package, where the external laser may be integrated into the LiDAR system. Using external laser components increase LiDAR system form factor and cost, and lead to manufacturing challenges with integrating LiDAR sensors into autonomous vehicles, including increasing bill of materials (BOM) costs of the legacy LiDAR system. In addition, legacy systems use a common thermal solution that does not thermally isolate a PIC within a package. For example, legacy systems are not able to thermally isolate multiple PICs within a package, or enable independent thermal control of the multiple PICs. This is particularly true when the multiple PICs may each have different thermal requirements.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

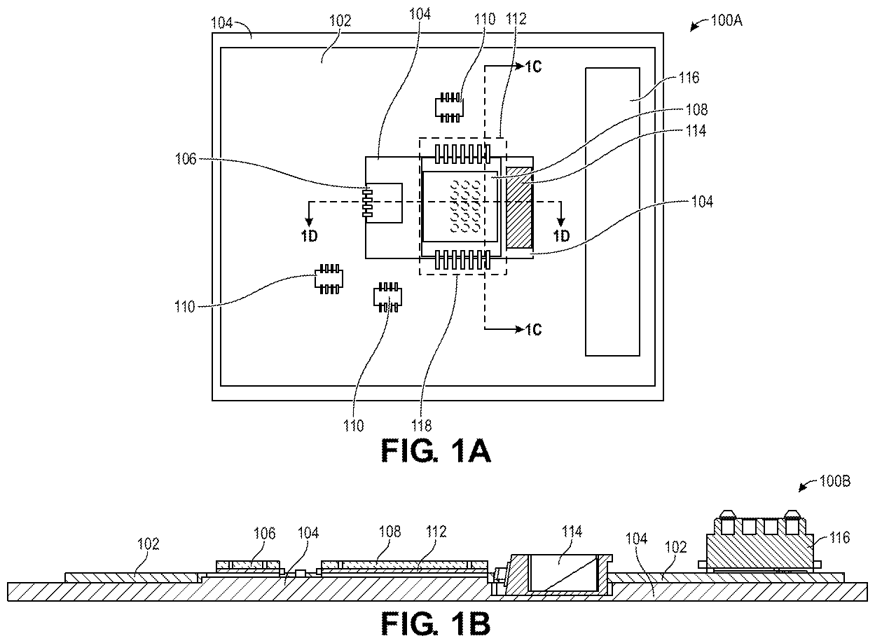

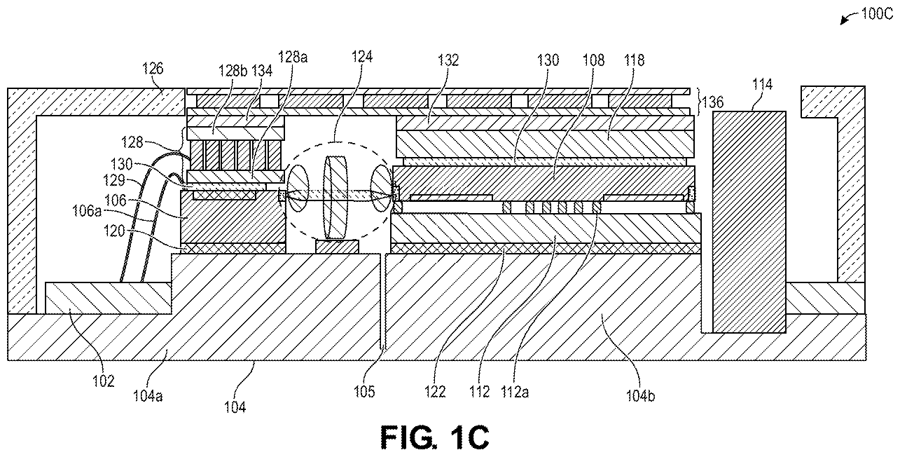

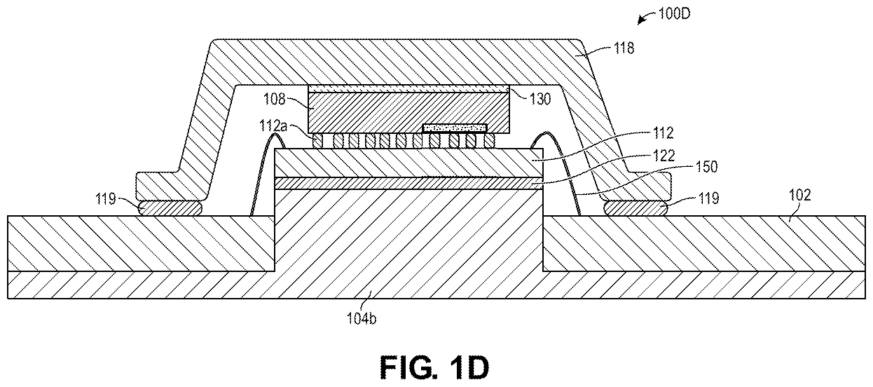

FIGS. 1A-1D illustrate a top-down view and cross section side views of a package that includes multiple PICs that are optically coupled with each other and that include a thermal electric cooler (TEC), in accordance with various embodiments. FIG. 1A shows package 100A that is a top-down cross section view that includes a substrate 102 that may include an optical bench 104 within all or part of the substrate or PCB (Printed Circuit Board) 102. In embodiments, a laser PIC die 106 may be physically coupled with the optical bench 104, and a transceiver PIC die 108 may be physically and electrically coupled with an interposer 112, that in turn may be physically coupled with the optical bench 104 and electrically coupled with the substrate 102. A heat spreader 118 may be thermally coupled with a top of the transceiver PIC die 108.

In embodiments, the optical bench 104 may be used as a support platform that is designed to be very rigid with a minimum amount of deflection during operation. This facilitates the alignment of optical elements attached to the optical bench 104, for example laser PIC die 106 and transceiver PIC die 108, staying within optical alignment tolerances. In embodiments, the optical bench 104 may be made of a metal with low CTE to provide thermo-mechanical stability to the optical bench 104 during operating conditions, and in embodiments including Invar that includes iron and nickel, and may be represented as FeNi₃₆.

In embodiments, other dies 110 may be physically and/or electrically coupled with the substrate 102, and may be electrically coupled with the laser PIC die 106 and/or transceiver PIC die 108. In embodiments, the transceiver PIC die 108 may be optically coupled with a prism 114, which may be used to transmit or receive light via one or more light pathways through a top of the package, as discussed further below. In embodiments, the transceiver PIC die 108 may be electrically coupled with a connector 116.

FIG. 1B shows package 100B, which may be similar to package 100A, that shows a side view of an example of discreet components that include the laser PIC die 106, the transceiver PIC die 108 that is electrically and physically coupled to the interposer 112, the prism 114 that may be optically coupled with the transceiver PIC die 108, and the connector 116, which may be electrically coupled with the transceiver PIC die 108.

FIG. 1C shows package 100C, which may be similar to package 100A and 100B, that shows a cross section side view at cut 1C of FIG. 1A. Optical bench 104 as shown may be integrated in with PCB 102. Optical bench 104 may include an Invar metal that includes iron and nickel. In embodiments, optical bench 104 may have a low CTE value, which may match the lower CTE value of the silicon PIC dies 106, 108. The low CTE mis-match between the Invar chassis and the silicon PIC dies 106, 108 reduces thermo-mechanical stress within the package and reduces the delamination risk between the PIC silicon and other components of the package. In embodiments, the optical bench 104 may have a trench 105 within the optical bench 104 that separates a first optical bench area 104a from a second optical bench area 104b. Trench 105 within the optical bench 104 may be used to thermally isolate the first optical bench area 104a from the second optical bench area 104b. In embodiments, the trench 105 may be empty, since air has the worst thermal conductivity. A prism 114 may be physically coupled with the optical bench 104.

In embodiments, a laser PIC die 106 may be physically and thermally coupled with the first optical bench area 104a. In embodiments, the physical and thermal coupling may be achieved with an adhesive 120, with low thermal conductivity, such that all the heat generated by the laser PIC die 106, will be directed towards the top of the die, where the thermal solution is located. In embodiments, the laser PIC die 106 may be electrically coupled with the PCB 102 through a wire bond 106a. A transceiver PIC die 108 may be physically coupled with the second optical bench area 104b. In embodiments, the transceiver PIC die 108 may be electrically coupled with an interposer 112. In embodiments, the interposer 112 may be a substrate with one or more electrically conductive layers to route signals and/or power between the transceiver PIC die 108 and the PCB 102. In embodiments, the interposer 112 may include silicon. In embodiments, connections 112a, such as flip chip connections, may electrically couple the transceiver PIC die 108 with the interposer 112. The interposer 112 may be physically coupled with the second optical bench area 104b using an adhesive 122, with low thermal conductivity, such that all the heat generated by the transceiver PIC die 108, will be directed towards the top of the die, where the thermal solution is located.

The transceiver PIC die 108 is optically coupled with the laser PIC die 106 using optical components 124. In embodiments, the optical connectivity components 124 may include lenses and/or isolators. In embodiments, at least some of the optical connectivity components 124 may be physically coupled with the optical bench 104 and optically coupled with the laser PIC die 106 and the transceiver PIC die 108. As shown, some of the optical connectivity components 124 are physically coupled with the first optical bench area 104a, however in other embodiments (not shown) they may be physically coupled with the second optical bench area 104b.

Note that in embodiments discussed further below, access may be provided to the optical connectivity components 124, for example for installation, repair, or alignment adjustment, after the package 100C has been manufactured. In embodiments, a cover 126, that may extend from the optical bench 104 and/or the PCB 102 and surround the laser PIC die 106 and the transceiver PIC die 108, may include a hole or an access port (not shown but discussed below) to provide access to the optical components 124. In embodiments, the cover 126 may be referred to as a housing.

A TEC 128, that includes a cold side 128a and a hot side 128b opposite the cold side 128a, may be thermally coupled with the laser PIC die 106. In embodiments, this coupling may be done through an adhesive 130 that may have a high thermal conductivity. The TEC 128 may be electrically coupled with the PCB 102 using wire bonding 129. In this configuration, the TEC 128 may be used to manage the operating temperature of the laser PIC die 106.

A heat spreader 118 may be thermally coupled to the transceiver PIC die 108 using a TIM 130. In embodiments, the heat spreader 118 may include copper. A main TEC 136 may be thermally coupled with the TEC 128 using a TIM 134. The main TEC 136 may also be thermally coupled with the heat spreader 118 using a TIM 132.

FIG. 1D shows package 100D, that may be similar to package 100C that shows a cross section side view at cut 1D of FIG. 1A. As shown, the heat spreader 118 is thermally coupled with the transceiver PIC die 108 using TIM 130. In this embodiment, the heat spreader 118 wraps around the package cross section down to a surface of the substrate 102, which may be a printed circuit board (PCB). In embodiments, there may be a sealant adhesive material 119 between the heat spreader 118 and the substrate 102, to physically couple the heat spreader 118 to the substrate 102. In embodiments, there may be a wire bonding 150 that electrically couples the interposer 112 with the substrate 102. The transceiver PIC die 108 is physically and electrically coupled with the interposer 112 using, in embodiments, flip chip connections 112a.

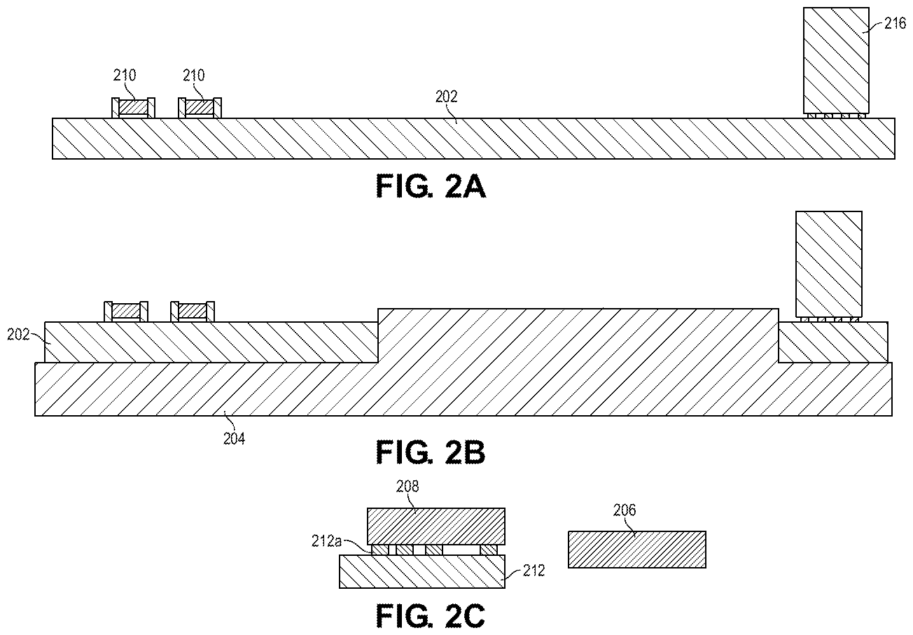

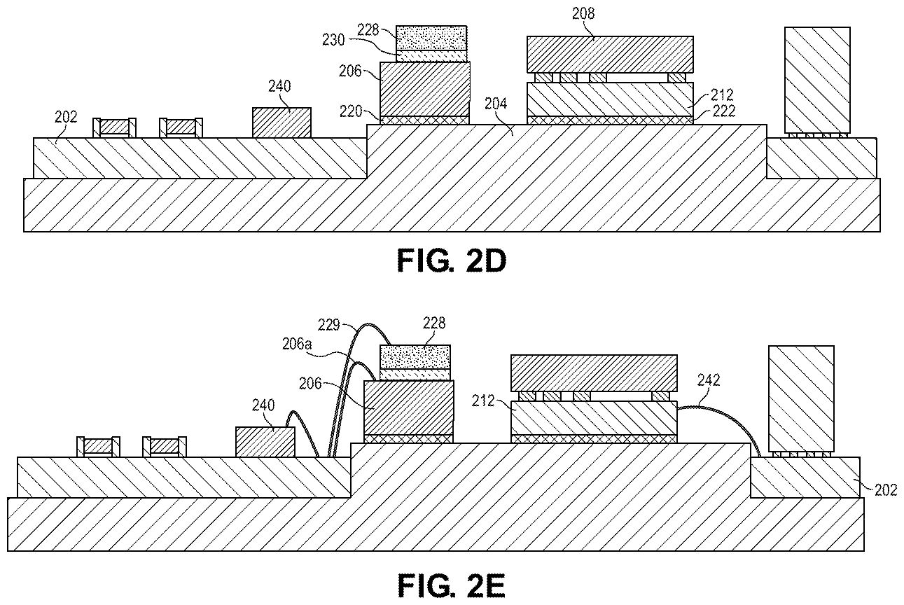

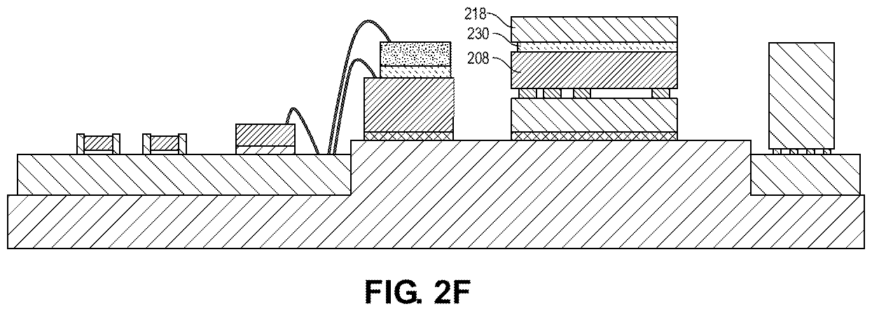

FIGS. 2A-2F illustrate stages in a manufacturing process for creating a package that includes multiple PICs that are optically coupled with each other, in accordance with various embodiments. The stages described with respect to FIGS. 2A-2F may be used to construct portions of packages that may be similar to the package as described with respect to FIGS. 1A-1D.

FIG. 2A illustrates a cross section side view of a stage in the manufacturing process that includes providing a substrate 202, which may be similar to substrate 102 of FIG. 1A, coupling one or more dies 210, which may be similar to dies 110 of FIG. 1A, to a surface of the substrate 202. In addition, a connector 216, which may be similar to connector 116 of FIG. 1A, may also be applied to the side of the substrate 202. In embodiments, surface mount technology (SMT) techniques may be used to apply these components to the substrate 202.

FIG. 2B illustrates a cross section side view of a stage in the manufacturing process where an optical bench 204, which may be similar to optical bench 104 of FIG. 1A, is coupled with the substrate 202. In various embodiments, the substrate 202 may be on portions of the optical bench 204. In embodiments, the optical bench 204 may be embedded on a surface of the substrate 202 (not shown). In embodiments, the optical bench 204 may be referred to as a chassis.

FIG. 2C illustrates a cross section side view of a stage in the manufacturing process where a laser PIC die 206, a transceiver PIC die 208, and an interposer 212 are identified. These may be similar to laser PIC die 106, transceiver PIC die 108, an interposer 112 of FIG. 1A. The transceiver PIC die 208 may be physically and electrically coupled with the interposer 212 using flip chip connections 212a, which may be similar to connections 112a of FIG. 1C. In embodiments, the connections 212a may include solder bumps. In embodiments, techniques used in this stage may include known techniques for die preparation, chip on wafer assembly, back grinding, mechanical dicing, or stealth dicing.

FIG. 2D illustrates a cross section side view of a stage in the manufacturing process where the laser PIC die 206, the transceiver PIC die 208, and interposer 212 are coupled with the optical bench 204. In embodiments, an adhesive 222 may be used to physically couple the interposer 212 with the optical bench 204, and an adhesive 220 may be used to physically couple the laser PIC die 206 with the optical bench 204.

In embodiments, a TEC 228, which may be similar to TEC 128 of FIG. 1C, may be thermally coupled to the laser PIC die 206 using an TIM 230. A trans-impedance amplifier (TIA) 240 may be physically and electrically coupled with the substrate 202.

FIG. 2E illustrates a cross section side view of a stage in the manufacturing process where the interposer 212 is electrically coupled with the substrate 202 using wire bonding 242. The TEC 228 is electrically coupled with the substrate 202 and/or the TIA 240 using wire bonding 229, which may be similar to wire bonding 129 of FIG. 1C. The laser PIC die 206 is electrically coupled with the substrate 202 and/or the TIA 240 using wire bonding 206a which may be similar to wire bonding 106a of FIG. 1C.

FIG. 2F illustrates a cross section side view of a stage in the manufacturing process where a heat spreader 218, which may be similar to heat spreader 118 of FIG. 1C, is thermally coupled with the transceiver PIC die 208 using TIM 230.

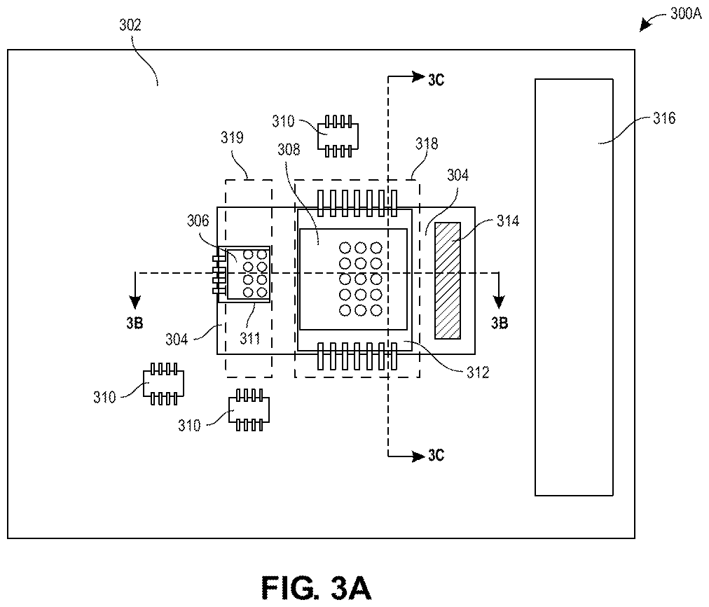

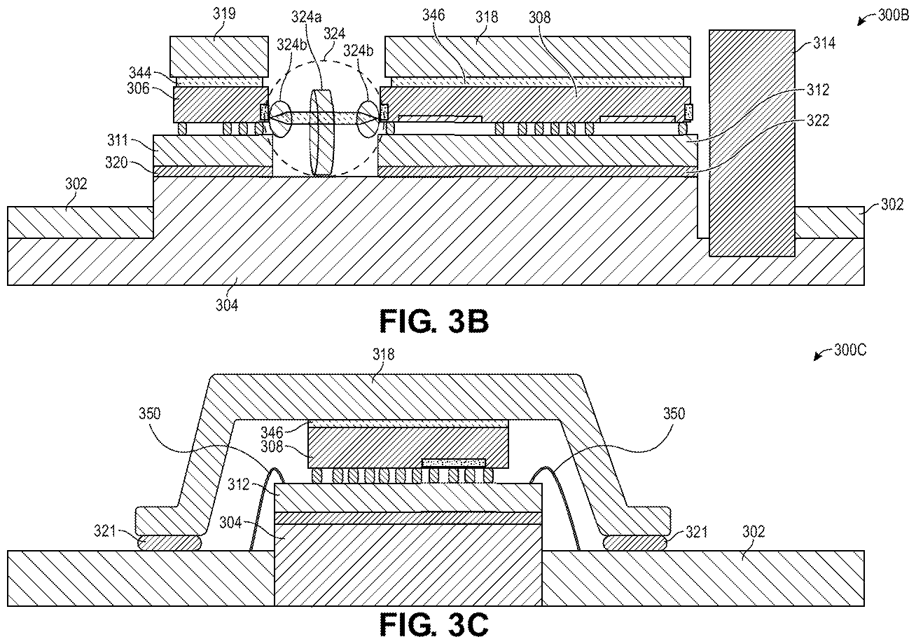

FIGS. 3A-3C illustrate a top-down and cross section side views of a package that includes multiple PICs that are optically coupled with each other and with heat spreaders coupled with the multiple PICs, in accordance with various embodiments. FIG. 3A shows a top-down cross-section view of package 300A, which may be similar to package 100A of FIG. 1A. A laser PIC die 306 and a transceiver PIC die 308 are coupled with an optical bench 304 that is physically coupled to a substrate 302, which may be similar to laser PIC die 106, transceiver PIC die 108, optical bench 104, and substrate 102 of FIG. 1A. Laser PIC die 306 and the transceiver PIC die 308 are optically coupled with each other through optical coupling components, such as optical coupling components 124 of FIG. 1. Die 310, which may be similar to dies 110 of FIG. 1A, are also coupled with the substrate 302.

A prism 314, which may be similar to prism 114 of FIG. 1A, may be physically coupled with the optical bench 304 and optically coupled with the transceiver PIC die 308. In embodiments, a connector 316, which may be similar to connector 116 of FIG. 1A, may be coupled with the substrate 302. In embodiments, a heat sink 318, which may be similar to heat spreader 118 of FIG. 1A, may be thermally coupled with the transceiver PIC die 308. The transceiver PIC die 308 may be physically and/or electrically coupled with an interposer 312, that may be similar to interposer 112 of FIG. 1A. The interposer 312 may be physically coupled with the optical bench 304 using an adhesive 322, which may be similar to adhesive 122 of FIG. 1C.

A heat spreader 319 may be thermally coupled with the laser PIC die 306. The laser PIC die 306 may be physically and/or electrically coupled with an interposer 311, which may be similar to interposer 112 of FIG. 1C.

FIG. 3B shows a cross section side view along cut 3B of FIG. 3A of package 300B, which may be similar to package 300A. Heat spreader 319 is thermally coupled with the laser PIC die 306 using a TIM 344, and heat spreader 318 is thermally coupled with transceiver PIC die 308 using a TIM 346. The laser PIC die 306 and the transceiver PIC die 308 are optically coupled using optical coupling components 324, similar to optical coupling components 124 of FIG. 1C that may include an isolator 324a and lenses 324b.

The heat spreader 318 may be thermally coupled with the transceiver PIC die 308, which may be physically and/or electrically coupled with an interposer 312. The interposer 312 may be physically coupled with the optical bench 304 using an adhesive 322, which may be similar to adhesive 122 of FIG. 1C. The heat sink 319 may be thermally coupled with the laser PIC die 306 which is physically and/or electrically coupled with an interposer 311. The interposer 311 may be coupled with the optical bench 304 by an adhesive 320, which may be similar to adhesive 120 of FIG. 1C.

FIG. 3C shows package 300C that may be similar to package 100D of FIG. 1D that shows a cross section side view cut 3C of FIG. 3A. As shown, the heat spreader 318 is thermally coupled with the transceiver PIC die 308 using TIM 346. In this embodiment the heat spreader 318 wraps around this package cross section down to a surface of the substrate 302, which may be a PCB. In embodiments, there may be a sealant adhesive material 321 between the heat spreader 318 and the substrate 302, to physically couple the heat spreader 318 to the substrate 302. In embodiments, there is a wire bonding 350 that electrically couples the interposer 312 with the substrate 302 to electrically couple the transceiver PIC die 308 with the substrate 302.

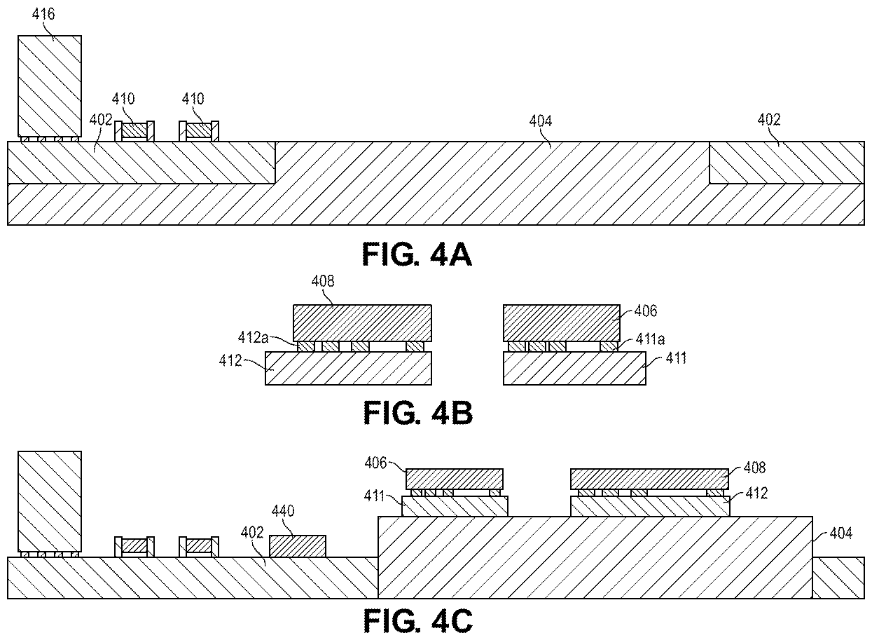

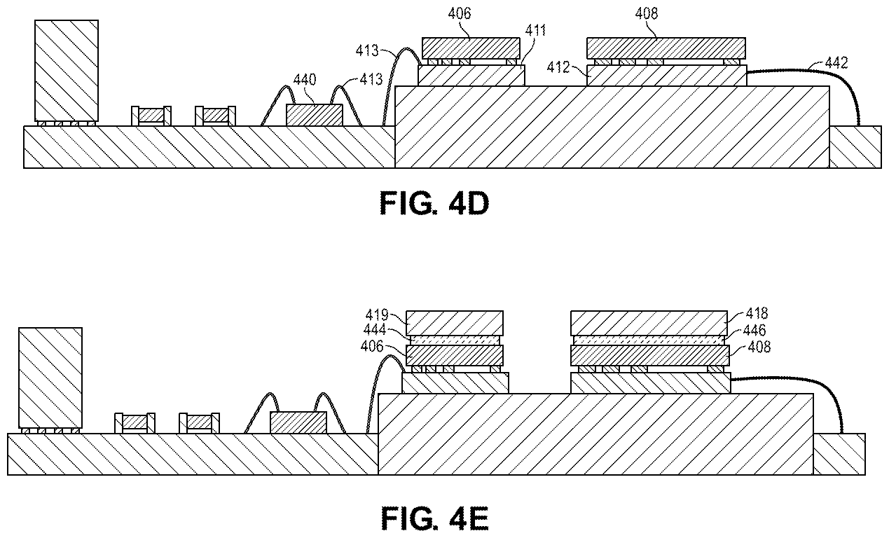

FIGS. 4A-4E illustrate stages in a manufacturing process for creating a package that includes multiple PICs that are optically coupled with each other and with heat spreaders coupled with the multiple PICs, in accordance with various embodiments. The stages described with respect to FIGS. 4A-4E may be used to construct portions of packages that may be similar to the package as described with respect to FIGS. 3A-3C.

FIG. 4A illustrates a cross section side view of a stage in the manufacturing process that includes providing a substrate 402, which may be similar to substrate 302 of FIG. 3A, coupling one or more dies 410, which may be similar to dies 310 of FIG. 3A, to a surface of the substrate 402. In addition, a connector 416, which may be similar to connector 316 of FIG. 3A, may also be applied to the side of the substrate 402. In embodiments, surface mount technology (SMT) techniques may be used to apply these components to the substrate 402.

An optical bench 404, which may be similar to optical bench 304 of FIG. 3A, is coupled with the substrate 402. In various embodiments, the substrate 402 may be on portions of the optical bench 404. In embodiments, the optical bench 404 be embedded on a surface of the substrate 402 (not shown).

FIG. 4B illustrates a cross section side view of a stage in the manufacturing process where a laser PIC die 406, an interposer 411, a transceiver PIC die 408, and an interposer 412 are identified. These may be similar to laser PIC die 306, interposer 311, transceiver PIC die 308, and interposer 312 of FIG. 3A. The transceiver PIC die 408 may be physically and electrically coupled with the interposer 412, using flip chip electrical connections 412a, and the laser PIC die 406 may be physically and electrically coupled with the interposer 411 using flip chip electrical connections 411a. In embodiments, techniques used in this stage may include known techniques for die preparation, chip on wafer assembly, back grinding, mechanical dicing or stealth dicing.

FIG. 4C illustrates a cross section side view of a stage in the manufacturing process where the laser PIC die 406 and interposer 411, the transceiver PIC die 408 and interposer 412 are coupled with the optical bench 404. A TIA 440, which may be similar to TIA 240 of FIG. 2D, may be physically and electrically coupled with the substrate 402.

FIG. 4D illustrates a cross section side view of a stage in the manufacturing process where the interposer 412 is electrically coupled with the substrate 402 using wire bonding 442 and the interposer 411 is electrically coupled with the substrate 402 and/or the TIA 440 using wire bonding 413.

FIG. 4E illustrates a cross section side view of a stage in the manufacturing process where a heat spreader 418 is thermally coupled with the transceiver PIC die 408 using a TIM 446, which may be similar to heat spreader 318, transceiver PIC die 308, and TIM 346 of FIG. 3B. In embodiments, heat spreader 419 is thermally coupled with the laser PIC die 406 using TIM 444, which may be similar to heat spreader 319, laser PIC die 306, and TIM 344 of FIG. 3B.

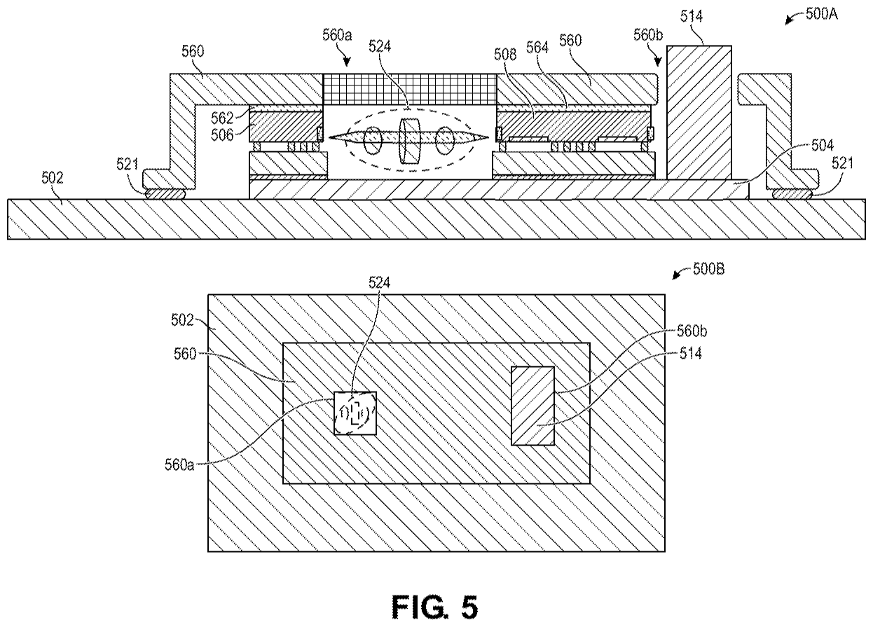

FIG. 5 illustrates a top-down view and a cross section side view of a package that includes multiple PICs that are optically coupled with each other, and that are surrounded by a heat spreader with a cut out, in accordance with various embodiments. Package 500A is a cross section side view that may be similar to package 300B of FIG. 3B. Package 500B is a top-down view. Optical bench 504 may be on a substrate 502, which may be similar to optical bench 304 and substrate 302 of FIG. 3B. Laser PIC die 506 and transceiver PIC die 508, which may be similar to laser PIC die 306 and transceiver PIC die 308 of FIG. 3B, may be partially enclosed by a heat spreader 560. The laser PIC 506 and the transceiver PIC die 508 are optically coupled with each other through optical coupling components 524, which may be similar to optical coupling components 324 of FIG. 3B.

In embodiments, the heat spreader 560 may extend from the substrate 502, and come into thermal contact with the laser PIC die 506 and the transceiver PIC die 508. In embodiments, there may be a sealant adhesive material 521, which may be similar to sealant adhesive material 321 of FIG. 3C, between the heat spreader 560 and the substrate 502. In embodiments, a TIM material 562 may thermally couple the laser PIC die 506 with the heat spreader 560, and a TIM material 564 may thermally couple the transceiver PIC die 508 with the heat spreader 560.

In embodiments, an opening 560a, which also may be referred to as a cutout, may be formed in the heat spreader 560 that allow access to the optical coupling components 524. This access may allow the installation, adjustment, or removal of the optical coupling components 524. In embodiments, another opening 560b may be formed to accommodate a prism 514, which may be similar to prism 314 of FIG. 3B, to allow light to be transmitted to and/or received from outside of the package 500A.

Note that in embodiments, the heat spreader 560 may also serve as a cover for the package 500A, which may be similar to cover 126 of FIG. 1C.

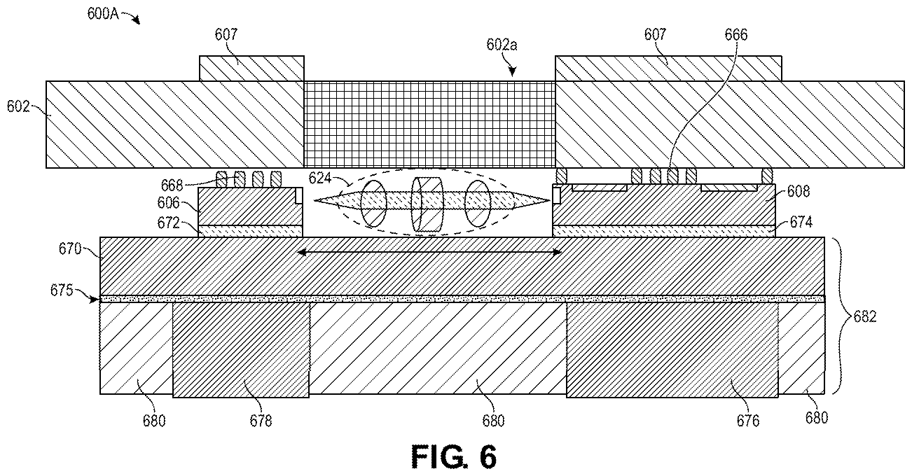

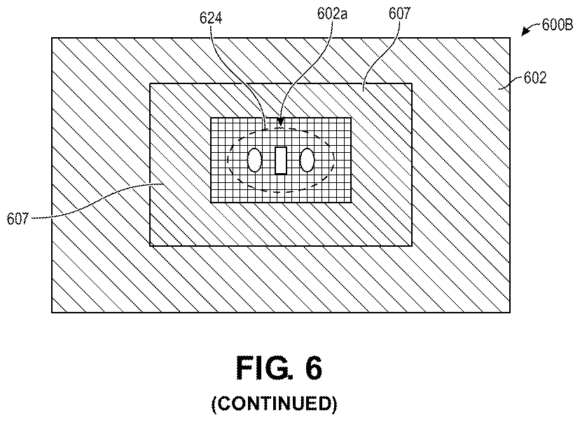

FIG. 6 illustrates a top-down view and a cross section side view of a package that includes multiple PICs that are optically coupled with each other with a first substrate physically coupled with a first side of the multiple PICs and a second substrate physically coupled with a second side of the multiple PICs opposite the first side, in accordance with various embodiments. Package 600A is a cross section side view that includes laser PIC die 606 and transceiver PIC die 608 that are physically and electrically coupled with a substrate 602. In embodiments, these may be similar to laser PIC die 506 and transceiver PIC die 508 of FIG. 5. The laser PIC die 606 and transceiver PIC die 608 are physically and electrically coupled to a substrate 602. The laser PIC die 606 may be coupled with the substrate 602 using interconnects 668, and the transceiver PIC die 608 may be coupled with the substrate 602 using interconnects 666. In embodiments, the interconnects 666, 668 may be solder interconnects. In embodiments, they may have a 400 μm pitch, and a 10 mil size, to improve solder joint reliability with larger ball size. In embodiments, they may include a low-temperature solder.

In embodiments, the laser PIC die 606 and the transceiver PIC die 608 are optically coupled using optical coupling components 624, which may be similar to optical coupling components 524 of FIG. 5. The substrate 602 may include a cutout 602a that provides access to the optical coupling components 624, for example for installation, repair, or removal. In embodiments, the cutout 602a may have a suitable dimension that enables optimum access to the optical coupling components 624.

A stiffener 607 may be physically coupled to a side of the substrate 602. In embodiments, the stiffener 607 may be proximate to the cutout 602a. In embodiments, the stiffener 607 may include stainless steel, or some other rigid material. A silicon spacer 670 may be physically and thermally coupled with the laser PIC die 606 using a TIM 672, and may be physically and thermally coupled with the transceiver PIC die 608 using a TIM 674. In embodiments the TIM 672, 674 may be thermal adhesives with a high glass transition temperature (Tg). The Tg is the temperature at which a polymer material changes from a hard and relatively brittle “glasssy” state into a viscous or rubbery state as the temperature is increased. A high Tg material provides thermo-mechanical stability to the physical coupling of the PIC dies 608 and 606 to the silicon spacer 670 during subsequent thermal operations in the assembly process and during the thermal operating conditions of the package.

The silicon spacer 670, may also be thermally coupled with a second TIM 675 at a side opposite the side coupled with the laser PIC die 606 and the transceiver PIC die 608. Multiple TECs 676, 678 maybe coupled with the second TIM 675, and may be located proximate to the transceiver PIC die 608 and the laser PIC die 606, respectively. The TECs 676, 678 may be embedded into or surrounded by a backing plate 680. In embodiments, the backing plate 680 may include copper or aluminum nitride. In embodiments, the combined silicon spacer 670, the second TIM 675, and the backing plate 680 provide a rigid stage 682, which may provide a very rigid platform, with very little deflection during operation, that may be used to secure the positions and optical alignment of the laser PIC die 606 and the transceiver PIC die 608.

In embodiments, a CTE of the silicon spacer 670, a CTE of the laser PIC die 606, and a CTE of the transceiver PIC die 608 may be similar. In embodiments, this may be used instead of a optical bench such as optical bench 104 of FIG. 1C, due to the silicon spacer 670 having a greater thermal isolation property as compared to an Invar metal that may be in an optical bench. Package 600B, which may be similar to package 600A, provides a top-down view.

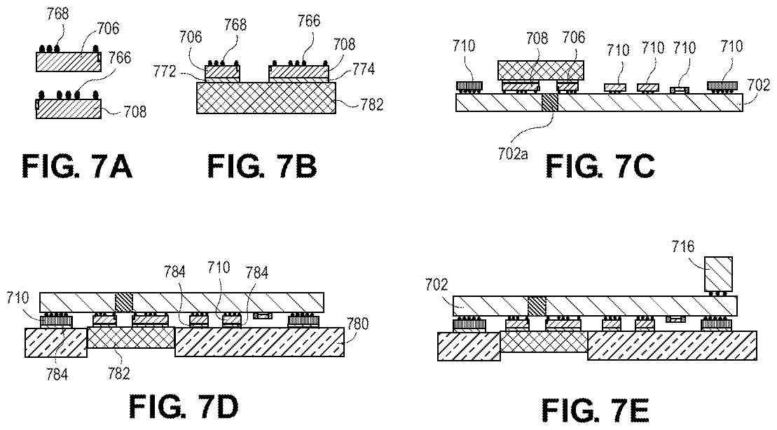

FIGS. 7A-7E illustrate stages in a manufacturing process for creating a package that includes multiple PICs that are optically coupled with each other with a first substrate physically coupled with a first side of the multiple PICs and a second substrate physically coupled with a second side of the multiple PICs opposite the first side, in accordance with various embodiments. The stages described with respect to FIGS. 7A-7E may be used to construct portions of packages that may be similar to the package 600A as described with respect to FIG. 6.

FIG. 7A illustrates a cross section side view of a stage in the manufacturing process that includes providing a laser PIC die 706 and a transceiver PIC die 708, that may be similar to laser PIC die 606 and transceiver PIC die 608 of FIG. 6. In embodiments, interconnects 766, which may be similar to interconnects 666 of FIG. 6, may be placed on the transceiver PIC die 708, and interconnects 768, which may be similar to interconnects 668 of FIG. 6, may be placed on the laser PIC die 706.

FIG. 7B illustrates a cross section side view of a stage in the manufacturing process where the laser PIC die 706 and the transceiver PIC die 708 are coupled with a rigid stage 782, which may be similar to rigid stage 682 of FIG. 6. The laser PIC die 706 may be coupled with the rigid stage 782 using a thermal adhesive 772, which may be similar to TIM 672 of FIG. 6. The transceiver PIC die 708 to be coupled with the rigid stage 782 using a thermal adhesive 774, which may be similar to TIM 674 of FIG. 6.

FIG. 7C illustrates a cross section side view of a stage in the manufacturing process where the result of FIG. 7B is electrically and physically coupled to the substrate 702, which may be similar to substrate 602 of FIG. 6. In embodiments, this coupling may be performed using techniques related to SMT. In embodiments, the substrate 702 may include other dies 710. Note that the cutout 702a, which may be similar to cutout 602a of FIG. 6, may be positioned between the laser PIC die 706 and the transceiver PIC die 708.

FIG. 7D illustrates a cross section side view of a stage in the manufacturing process where the result of FIG. 7C is flipped and a chassis 780 is coupled with the rigid stage 782. In embodiments, an adhesive 784, which may be a thermal adhesive, may be applied to a surface of the dies 710 to facilitate bonding with the chassis 780.

FIG. 7E illustrates a cross section side view of a stage in the manufacturing process where a connector 716, which may be similar to connector 116 of FIG. 1A, is coupled with the substrate 702.

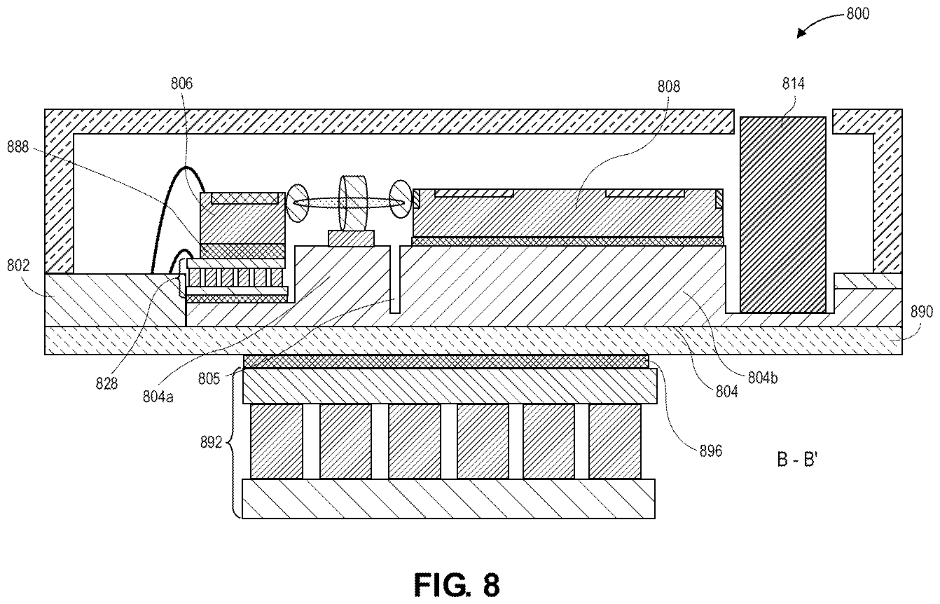

FIG. 8 illustrates a cross section side view of a package that includes multiple PICs that are optically coupled with each other, where the multiple PICs are physically coupled with an optical bench that includes Invar, and are thermally managed by a TEC, in accordance with various embodiments. Package 800, which may be similar to package 100C of FIG. 1C, includes a laser PIC die 806 that is thermally coupled with a TEC 828, which may be similar to laser PIC die 106 and TEC 128 of FIG. 1C. A thermally conductive layer 888 may thermally couple the laser PIC die 806 and the TEC 828. Note that the laser PIC die 806 is optically coupled with the transceiver PIC die 808, which may be similar to transceiver PIC die 108 of FIG. 1C.

Note that similar to package 100C of FIG. 1C, optical bench 804 may be split by trench 805 into a first optical bench area 804a and a second optical bench area 804b. A prism 814 may be on the second optical bench area 804b, and optically coupled with the transceiver PIC die 808. As shown, the TEC 828 may be recessed within the first optical bench area 804a.

In embodiments, a cold plate 890 may be thermally coupled with the optical bench 804, and may be coupled with the substrate 802. A main TEC 892 may be thermally coupled with the cold plate 890 by TIM layer 896.

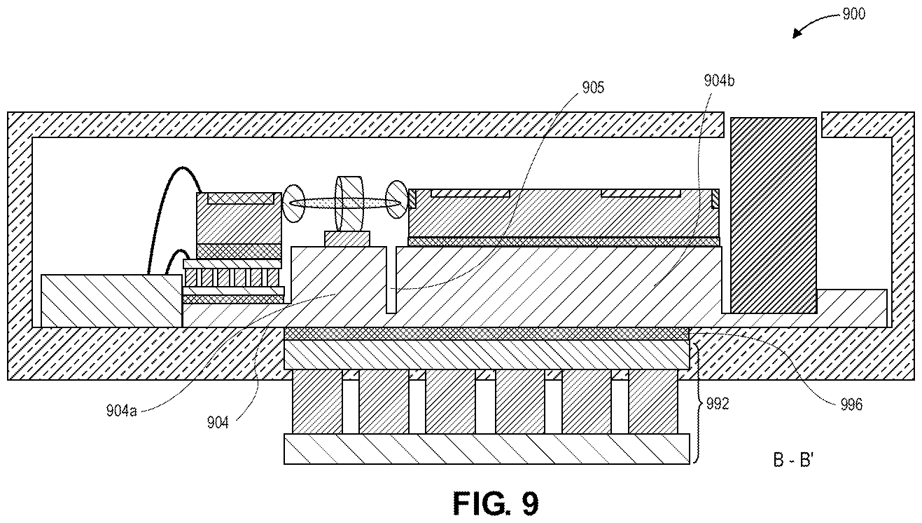

FIG. 9 illustrates a cross section side view of a package that includes multiple PICs that are optically coupled with each other, where the multiple PICs are thermally managed by multiple TEC, in accordance with various embodiments. Package 900, which may be similar to package 800 of FIG. 8, includes an optical bench 904 that may be split by trench 905 into a first optical bench area 904a and a second optical bench area 904b. These may be similar to optical bench 804, trench 805, first optical bench area 804a and second optical bench area 804b.

Instead of a cold plate 890 of FIG. 8, the main TEC 992, which may be similar to main TEC 892 of FIG. 8, is directly thermally and physically coupled with the optical bench 904. In embodiments, a TIM 996, which may be similar to TIM 896 of FIG. 8, may be used to thermally and physically couple TEC 992 with the optical bench 904. In embodiments, the TEC 992 may be directly thermally and physically couple with any portion of the optical bench 904, and as shown may directly thermally and physically couple with the first optical bench area 904a and the second optical bench area 904b.

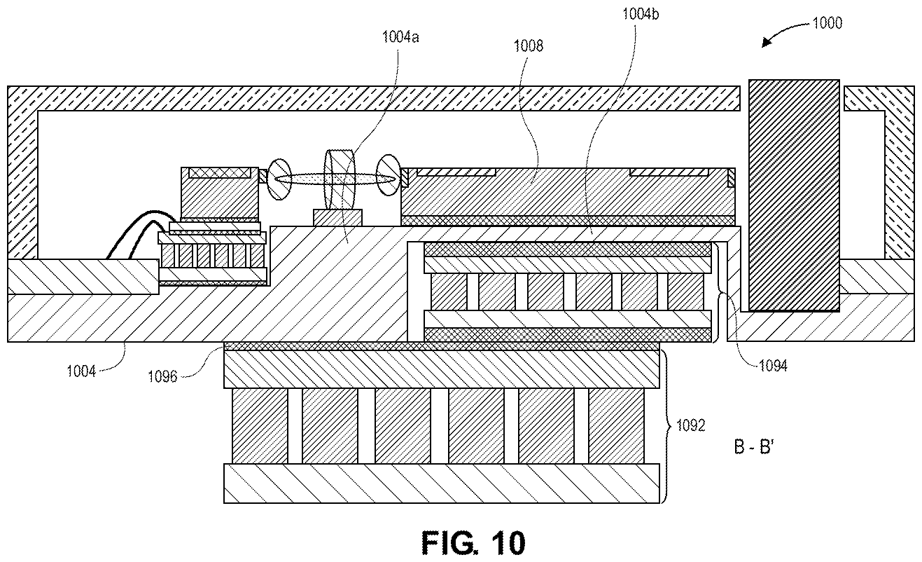

FIG. 10 illustrates a cross section side view of a package that includes multiple PICs that are optically coupled with each other and surrounded by a chassis that includes a cut out to thermally couple a TEC with the multiple PICs, in accordance with various embodiments. Package 1000, which may be similar to package 900 of FIG. 9, includes an optical bench 1004 that may be split into a first optical bench area 1004a, which may be similar to first optical bench area 904a of FIG. 9, and a second optical bench area 1004b.

In this embodiment, another TEC 1094 is thermally coupled with the second optical bench area 1004b, and thermally coupled with TEC 1092 using a TIM 1096, which may be similar to TEC 992 and TIM 996 of FIG. 9. This may allow the transceiver PIC die 1008, which may be similar to transceiver PIC die 800 of FIG. 8, to receive additional cooling or improved thermal management.

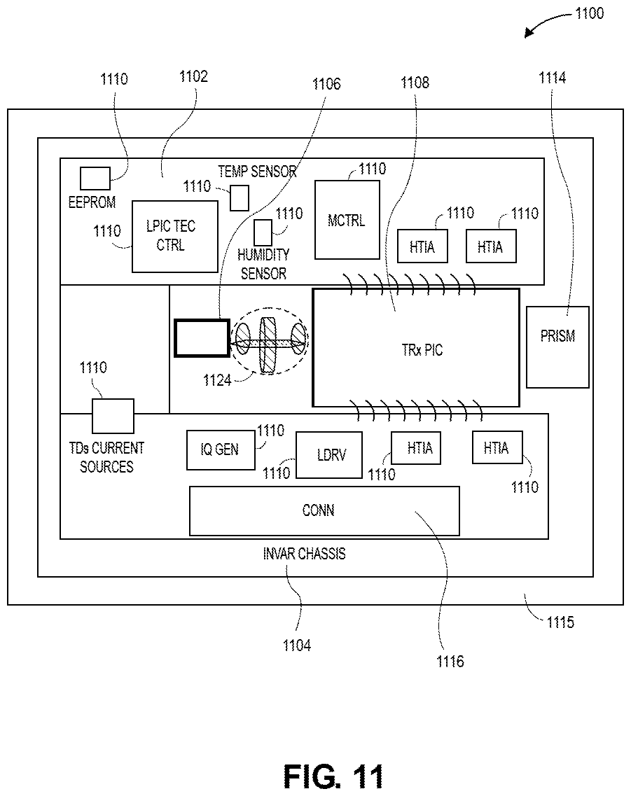

FIG. 11 illustrates a top-down cross-section view of a layout of a package that includes multiple PICs that are optically coupled with each other, with the package including optical components, in accordance with various embodiments. Package 1100 includes a transceiver PIC die 1108, and a laser PIC die 1106, which may be similar to transceiver PIC die 808 and laser PIC die 806 of FIG. 8, that are optically coupled with each other using optical coupling components 1124, that may include lenses and an isolator. Transceiver PIC die 1108 and laser PIC die 1106 are physically coupled with an Invar chassis 1104 that may be physically coupled with a substrate 1102, which may be similar to optical bench 804 and substrate 802 of FIG. 8. A prism 1114, which may be similar to prism 814 of FIG. 8, may be physically coupled with the substrate 1102 and optically coupled with the transceiver PIC die 1108. Connector 1116, which may be similar to connector 116 of FIG. 1, may also be physically and electrically coupled with the Invar chassis 1104. In embodiments, various other dies 1110, which may be similar to dies 110 of FIG. 1 may be present. In embodiments, a lid 1115 (partially shown) may enclose all or part of the package 1100.

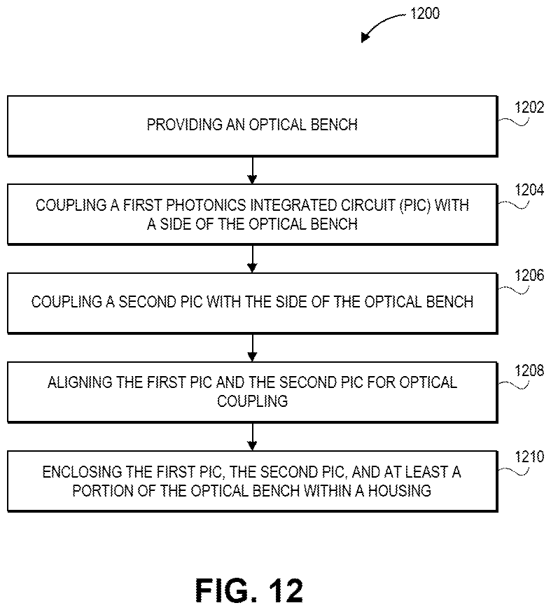

FIG. 12 illustrates an example of a process for manufacturing a package that includes multiple PICs that are optically coupled with each other, in accordance with various embodiments. Process 1200 may be performed by one or more elements, techniques, or systems that may be described herein, and in particular with respect to FIGS. 1A-11.

At block 1202, the process may include providing an optical bench. In embodiments, the optical bench may be similar to at least optical bench 104 of FIG. 1C, optical bench 304 of FIG. 3B, optical bench 504 of FIG. 5, or optical bench 804 of FIG. 8.

At block 1204, the process may further include coupling a first PIC with a side of the optical bench. In embodiments, the first PIC may be similar to at least laser PIC die 106 or transceiver PIC die 108 of FIG. 1A, laser PIC die 306 or transceiver PIC die 308 of FIG. 3C, laser PIC die 506 or transceiver PIC die 508 of FIG. 5, or laser PIC die 806 or transceiver PIC die 808 of FIG. 8.

At block 1206, the process may further include coupling a second PIC with the side of the optical bench. In embodiments, the second PIC may be similar to at least laser PIC die 106 or transceiver PIC die 108 of FIG. 1A, laser PIC die 306 or transceiver PIC die 308 of FIG. 3C, laser PIC die 506 or transceiver PIC die 508 of FIG. 5, or laser PIC die 806 or transceiver PIC die 808 of FIG. 8.

At block 1208, the process may further include aligning the first PIC and the second PIC for optical coupling. In embodiments, aligning may include positioning the first PIC or the second PIC on the optical bench. In other embodiments, aligning may also include inserting optical coupling components, such as optical coupling components 124 of FIG. 1C, between the first PIC and the second PIC.

At block 1210, the process may further include enclosing the first PIC, the second PIC, and at least a portion of the optical bench within a housing. In embodiments, the housing may be similar to cover 126 of FIG. 1C.

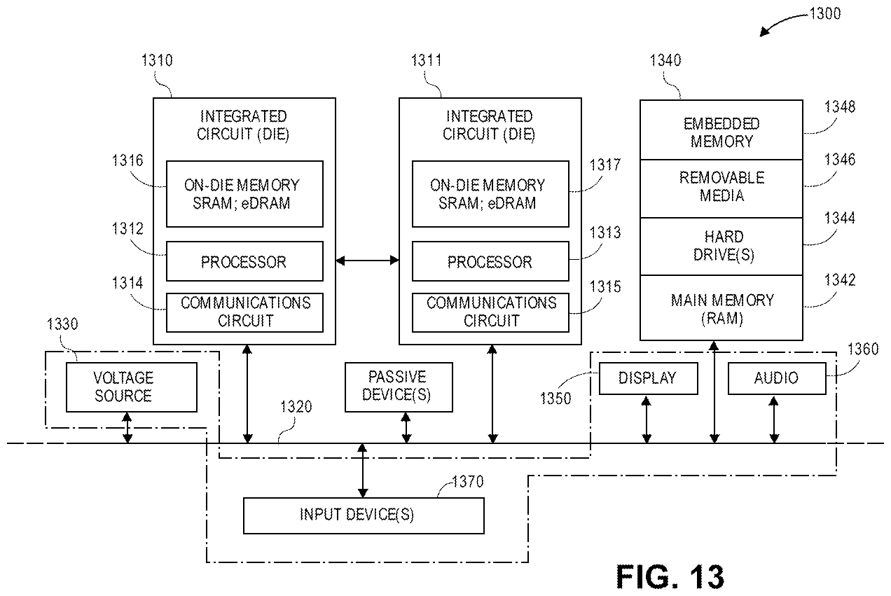

FIG. 13 is a schematic of a computer system 1300, in accordance with an embodiment of the present invention. The computer system 1300 (also referred to as the electronic system 1300) as depicted can embody a package with multiple PIC optically coupled with each other, according to any of the several disclosed embodiments and their equivalents as set forth in this disclosure. The computer system 1300 may be a mobile device such as a netbook computer. The computer system 1300 may be a mobile device such as a wireless smart phone. The computer system 1300 may be a desktop computer. The computer system 1300 may be a hand-held reader. The computer system 1300 may be a server system. The computer system 1300 may be a supercomputer or high-performance computing system.

In an embodiment, the electronic system 1300 is a computer system that includes a system bus 1320 to electrically couple the various components of the electronic system 1300. The system bus 1320 is a single bus or any combination of busses according to various embodiments. The electronic system 1300 includes a voltage source 1330 that provides power to the integrated circuit 1310. In some embodiments, the voltage source 1330 supplies current to the integrated circuit 1310 through the system bus 1320.

The integrated circuit 1310 is electrically coupled to the system bus 1320 and includes any circuit, or combination of circuits according to an embodiment. In an embodiment, the integrated circuit 1310 includes a processor 1312 that can be of any type. As used herein, the processor 1312 may mean any type of circuit such as, but not limited to, a microprocessor, a microcontroller, a graphics processor, a digital signal processor, or another processor. In an embodiment, the processor 1312 includes, or is coupled with, a package with multiple PIC optically coupled with each other, as disclosed herein. In an embodiment, SRAM embodiments are found in memory caches of the processor. Other types of circuits that can be included in the integrated circuit 1310 are a custom circuit or an application-specific integrated circuit (ASIC), such as a communications circuit 1314 for use in wireless devices such as cellular telephones, smart phones, pagers, portable computers, two-way radios, and similar electronic systems, or a communications circuit for servers. In an embodiment, the integrated circuit 1310 includes on-die memory 1316 such as static random-access memory (SRAM). In an embodiment, the integrated circuit 1310 includes embedded on-die memory 1316 such as embedded dynamic random-access memory (eDRAM).

In an embodiment, the integrated circuit 1310 is complemented with a subsequent integrated circuit 1311. Useful embodiments include a dual processor 1313 and a dual communications circuit 1315 and dual on-die memory 1317 such as SRAM. In an embodiment, the dual integrated circuit 1310 includes embedded on-die memory 1317 such as eDRAM.

In an embodiment, the electronic system 1300 also includes an external memory 1340 that in turn may include one or more memory elements suitable to the particular application, such as a main memory 1342 in the form of RAM, one or more hard drives 1344, and/or one or more drives that handle removable media 1346, such as diskettes, compact disks (CDs), digital variable disks (DVDs), flash memory drives, and other removable media known in the art. The external memory 1340 may also be embedded memory 1348 such as the first die in a die stack, according to an embodiment.

In an embodiment, the electronic system 1300 also includes a display device 1350, an audio output 1360. In an embodiment, the electronic system 1300 includes an input device such as a controller 1370 that may be a keyboard, mouse, trackball, game controller, microphone, voice-recognition device, or any other input device that inputs information into the electronic system 1300. In an embodiment, an input device 1370 is a camera. In an embodiment, an input device 1370 is a digital sound recorder. In an embodiment, an input device 1370 is a camera and a digital sound recorder.

As shown herein, the integrated circuit 1310 can be implemented in a number of different embodiments, including a package substrate having a package with multiple PIC optically coupled with each other, according to any of the several disclosed embodiments and their equivalents, an electronic system, a computer system, one or more methods of fabricating an integrated circuit, and one or more methods of fabricating an electronic assembly that includes a package substrate having a package with multiple PIC optically coupled with each other, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a package with multiple PIC optically coupled with each other embodiments and their equivalents. A foundation substrate may be included, as represented by the dashed line of FIG. 13. Passive devices may also be included, as is also depicted in FIG. 13.

### Examples

The following paragraphs describe examples of various embodiments.

Example 1 includes a package comprising: a substrate; a first photonics integrated circuit (PIC) coupled with a side of the substrate; a second PIC coupled with the side of the substrate; and wherein the first PIC and the second PIC are optically coupled with each other.

Example 2 includes the package of example 1, or of any other example or embodiment described herein, wherein at least a portion of the substrate is an optical bench, wherein the first PIC and the second PIC are coupled with a side of the optical bench.

Example 3 includes the package of example 2, or of any other example or embodiment described herein, wherein the optical bench includes a selected one or more of: iron, nickel, or Invar.

Example 4 includes the package of example 2, or of any other example or embodiment described herein, wherein the side of the optical bench is a first side; and further comprising: a trench extending across the first side of the optical bench, a bottom of the trench proximate to the second side of the optical bench opposite the first side; and wherein the trench is between the first PIC and the second PIC, and wherein the trench reduces thermal conductivity between the first PIC and the second PIC.

Example 5 includes the package of example 4, or of any other example or embodiment described herein, wherein the trench is filled with air.

Example 6 includes a package of example 1, or of any other example or embodiment described herein, further comprising an interposer between a side of the first PIC and a side of the substrate, wherein the interposer is electrically coupled with the PIC.

Example 7 includes a package of example 6, or of any other example or embodiment described herein, further comprising an electrical coupling between the interposer and a printed circuit board (PCB) that electrically couples the first PIC and the PCB.

Example 8 includes package of example 6, or of any other example or embodiment described herein, further comprising a TIM between a surface of the interposer and a surface of the substrate.

Example 9 includes the package of example 6, or of any other example or embodiment described herein, wherein the side of the first PIC is a first side; and further comprising: a second side of the first PIC opposite the first side; and a heat spreader thermally coupled with the second side of the first PIC.

Example 10 includes a package of example 1, or of any other example or embodiment described herein, further comprising a TEC that is thermally coupled with a side of the second PIC.

Example 11 includes the package of example 10, or of any other example or embodiment described herein, wherein the TEC has a cold side and a hot side opposite the cold side, wherein the cold side is thermally coupled with the side of the second PIC, and wherein the hot side is thermally coupled with a heat spreader.

Example 12 includes the package of example 11, or of any other example or embodiment described herein, wherein the TEC is electrically coupled with a PCB.

Example 13 includes a package of example 1, or of any other example or embodiment described herein, further comprising: a silicon spacer having a first side and a second side opposite the first side, the first side of the silicon spacer coupled with a side of the first PIC and with a side of the second PIC that is opposite the substrate; a first TIM between the side of the first PIC and the silicon spacer; a second TIM between the side of the second PIC and the silicon spacer; and one or more TEC thermally coupled with the second side of the silicon spacer.

Example 14 includes the package of example 13, or of any other example or embodiment described herein, further comprising a backing plate surrounding the one or more TEC, the backing plate thermally coupled with the second side of the silicon spacer.

Example 15 includes the package of example 13, or of any other example or embodiment described herein, further comprising an opening within the substrate proximate to an area between the first PIC and the second PIC that provides access to optical components optically coupling the first PIC and the second PIC.

Example 16 includes a package of example 1, or of any other example or embodiment described herein, wherein the first PIC or the second PIC include a selected one of: a LiDAR transceiver, a laser, a tunable external feedback laser (TEFL), or a wavelength switchable laser array (WSLA).

Example 17 is a package comprising: a substrate; a first photonics integrated circuit (PIC) coupled with a side of the substrate; a second PIC coupled with the side of the substrate, wherein the first PIC and the second PIC are optically coupled with each other; and a housing coupled with the substrate, the housing surrounds the first PIC and the second PIC.

Example 18 includes the package of example 17, or of any other example or embodiment described herein, wherein the first PIC is a plurality of first PICs, and wherein the second PIC is a plurality of second PICs.

Example 19 includes the package of example 17, or of any other example or embodiment described herein, wherein the substrate includes an Invar metal, and wherein the first PIC and the second PIC are coupled with the Invar metal.

Example 20 includes the package of example 19, or of any other example or embodiment described herein, further comprising a cold plate on a side of the Invar metal opposite the first PIC and the second PIC.

Example 21 includes the package of example 20, or of any other example or embodiment described herein, further comprising a thermoelectric cooler (TEC) thermally coupled with the cold plate.

Example 22 is a method comprising: providing an optical bench; coupling a first photonics integrated circuit (PIC) with a side of the optical bench; coupling a second PIC with the side of the optical bench; aligning the first PIC and the second PIC for optical coupling; and enclosing the first PIC, the second PIC, and at least a portion of the optical bench within a housing.

Example 23 includes the method of example 22, or of any other example or embodiment described herein, wherein coupling the second PIC with the side of the optical bench further includes: coupling the second PIC with a first side of an interposer that has the first side and a second side opposite the first side; and coupling the second side of the interposer with the side of the optical bench.

Example 24 includes the method of example 22, or of any other example or embodiment described herein, wherein enclosing within a housing further includes: thermally coupling a heat spreader to the first PIC and/or to the second PIC; and thermally coupling the heat spreader with the housing.

Example 25 includes the method of example 22, or of any other example or embodiment described herein, wherein aligning the first PIC of the second PIC for optical coupling further includes inserting optical components between the first PIC and the second PIC through an opening in the housing.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. A package comprising:
a substrate;
a first photonics integrated circuit (PIC) coupled with a side of the substrate;
a second PIC coupled with the side of the substrate; and
wherein the first PIC and the second PIC are optically coupled with each other.

2. The package of claim 1, wherein at least a portion of the substrate is an optical bench, wherein the first PIC and the second PIC are coupled with a side of the optical bench.

3. The package of claim 2, wherein the optical bench includes a selected one or more of: iron, nickel, or Invar.

4. The package of claim 2, wherein the side of the optical bench is a first side; and further comprising:
a trench extending across the first side of the optical bench, a bottom of the trench proximate to the second side of the optical bench opposite the first side; and
wherein the trench is between the first PIC and the second PIC, and wherein the trench reduces thermal conductivity between the first PIC and the second PIC.

5. The package of claim 4, wherein the trench is filled with air.

6. The package of claim 1, further comprising an interposer between a side of the first PIC and a side of the substrate, wherein the interposer is electrically coupled with the PIC.

7. The package of claim 6, further comprising an electrical coupling between the interposer and a printed circuit board (PCB) that electrically couples the first PIC and the PCB.

8. The package of claim 6, further comprising a thermal interface material (TIM) between a surface of the interposer and a surface of the substrate.

9. The package of claim 6, wherein the side of the first PIC is a first side; and further comprising:
a second side of the first PIC opposite the first side; and
a heat spreader thermally coupled with the second side of the first PIC.

10. The package of claim 1, further comprising a thermoelectric cooler (TEC) that is thermally coupled with a side of the second PIC.

11. The package of claim 10, wherein the TEC has a cold side and a hot side opposite the cold side, wherein the cold side is thermally coupled with the side of the second PIC, and wherein the hot side is thermally coupled with a heat spreader.

12. The package of claim 11, wherein the TEC is electrically coupled with a PCB.

13. The package of claim 1, further comprising:
a silicon spacer having a first side and a second side opposite the first side, the first side of the silicon spacer coupled with a side of the first PIC and with a side of the second PIC that is opposite the substrate;
a first TIM between the side of the first PIC and the silicon spacer;
a second TIM between the side of the second PIC and the silicon spacer; and
one or more TEC thermally coupled with the second side of the silicon spacer.

14. The package of claim 13, further comprising a backing plate surrounding the one or more TEC, the backing plate thermally coupled with the second side of the silicon spacer.

15. The package of claim 13, further comprising an opening within the substrate proximate to an area between the first PIC and the second PIC.

16. The package of claim 1, wherein the first PIC or the second PIC include a selected one of: a LiDAR transceiver, a laser, a tunable external feedback laser (TEFL), or a wavelength switchable laser array (WSLA).

17. A package comprising:
a substrate;
a first photonics integrated circuit (PIC) coupled with a side of the substrate;
a second PIC coupled with the side of the substrate, wherein the first PIC and the second PIC are optically coupled with each other; and
a housing coupled with the substrate, the housing surrounds the first PIC and the second PIC.

18. The package of claim 17, wherein the first PIC is a plurality of first PICs, and wherein the second PIC is a plurality of second PICs.

19. The package of claim 17, wherein the substrate includes an Invar metal, and wherein the first PIC and the second PIC are coupled with the Invar metal.

20. The package of claim 19, further comprising a cold plate on a side of the Invar metal opposite the first PIC and the second PIC.

21. The package of claim 20, further comprising a thermoelectric cooler (TEC) thermally coupled with the cold plate.

22. A method comprising:
providing an optical bench;
coupling a first photonics integrated circuit (PIC) with a side of the optical bench;
coupling a second PIC with the side of the optical bench;
aligning the first PIC and the second PIC for optical coupling; and
enclosing the first PIC, the second PIC, and at least a portion of the optical bench within a housing.

23. The method of claim 22, wherein coupling the second PIC with the side of the optical bench further includes:
coupling the second PIC with a first side of an interposer that has the first side and a second side opposite the first side; and
coupling the second side of the interposer with the side of the optical bench.

24. The method of claim 22, wherein enclosing within a housing further includes:
thermally coupling a heat spreader to the first PIC and/or to the second PIC; and
thermally coupling the heat spreader with the housing.

25. The method of claim 22, wherein aligning the first PIC of the second PIC for optical coupling further includes inserting optical components between the first PIC and the second PIC through an opening in the housing.
